(19) United States
(12) Patent Application Publication
(10) Pub. No.: US 2026/0053033 A1
(43) Pub. Date: Feb. 19, 2026

(54) PACKAGE SUBSTRATE AND MANUFACTURING METHOD THEREOF

(71) Applicant: AaltoSemi Inc., Nanjing City (CN)

(72) Inventors: Yang-Li WU, Nanjing City (CN); Yin-Ju CHEN, Nanjing City (CN); Sung-Kun LIN, Nanjing City (CN); Min-Yao CHEN, Nanjing City (CN); Andrew C. CHANG, Nanjing City (CN)

(73) Assignee: AaltoSemi Inc., Nanjing City (CN)

(21) Appl. No.: 19/266,927

(22) Filed: Jul. 11, 2025

(30) Foreign Application Priority Data
Aug. 16, 2024 (CN) 202411127681.8

(51) Int. Cl. H01L 23/14; H01L 21/48; H01L 23/498

(52) U.S. Cl. CPC H01L 23/14; H01L 21/486; H01L 23/49827

(57) ABSTRACT

Provided is a package substrate. In a manufacturing method thereof, by combining two extremely thin substrates to be processed on opposite sides of a carrier (and/or a support member), a first circuit layer and a second circuit layer are respectively formed on opposite sides of a core layer of the substrate. Therefore, the structural thickness required for the manufacturing process is increased such that the processability of the ultra-thin substrates is not limited by the equipment performance, thereby eliminating the need for specialized equipment and significantly reducing processing costs.

### CROSS-REFERENCE TO RELATED APPLICATIONS

This application claims priority to Chinese Patent Application 202411127681.8 filed on Aug. 16, 2024, the entire contents of which are incorporated herein by reference and made a part of this specification.

### BACKGROUND

### 1. Technical Field

The present disclosure relates to a semiconductor packaging technology, and more particularly, to a package substrate and a manufacturing method thereof that can reduce costs.

### 2. Description of Related Art

With the booming development of portable electronic products in recent years, all kinds of related products are gradually moving towards the trend of high density, high performance and light, thin, short and small and all kinds of package on package (POP) processes are also in line with the innovation, in order to be able to meet the light, thin, short, small and high-density requirements.

The POP manufacturing process is a technological solution for realizing 3D packaging by stacking multi-layer packaging, and has a high assembly density, high assembly efficiency, multi-functionality and other advantages. However, the POP manufacturing process for coupling solder balls to a core layer of a package substrate must consider processing conditions such as thinner thickness, low warpage, high-density patterning and laser drilling.

Unfortunately, in the manufacturing method of a conventional package substrate, conventional processing equipment has a risk of damage to the processing conditions for the minimum board thickness, thereby limiting the ability to process thinner substrates.

Disadvantageously, this requires a high investment cost to purchase specialized equipment for the entire process, resulting in a significant increase in processing costs.

Therefore, there is an urgent need to overcome the above-described problems of the above-mentioned prior art technology.

### SUMMARY

In view of the various shortcomings of the prior art, in an aspect the present disclosure provides a package substrate, which comprises: a core layer having a first side, a second side opposite to the first side, and a plurality of through holes communicating the first side with the second side, wherein the through holes are double tapered holes; a first circuit layer formed on the first side of the core layer; a first solder resist layer formed on the first side of the core layer and the first circuit layer, wherein a portion of a surface of the first circuit layer is exposed from the first solder resist layer; a second circuit layer formed on the second side of the core layer; a second solder resist layer formed on the second side of the core layer and the second circuit layer, wherein a portion of a surface of the second circuit layer is exposed from the second solder resist layer; and a conductive pillar formed in each of the plurality of through holes and electrically connecting the first circuit layer and the second circuit layer.

In an aspect, the present disclosure further provides a method of manufacturing a package substrate, and the method comprises: providing a substrate including a core layer and a metal layer formed on each of opposite surfaces of the core layer, wherein the core layer has a first side, a second side opposite to the first side, and a plurality of through holes communicating the first side with the second side, wherein the through holes are double tapered holes; bonding the substrate to each of opposite sides of a carrier, wherein each of the substrates is bonded to the carrier by the second side of the core layer; forming a first circuit layer on the first side of the core layer by means of the metal layer and forming a conductive pillar electrically connected to the first circuit layer in each of the plurality of through holes; forming a first solder resist layer on the first side of the core layer and the first circuit layer, wherein a portion of a surface of the first circuit layer is exposed from the first solder resist layer; removing the carrier; bonding the substrate to each of opposite sides of a support member, wherein each of the substrates is bonded to the support member by the first solder resist layer on the first side thereof; forming a second circuit layer electrically connected to the conductive pillar by means of the metal layer on the second side of the core layer; forming a second solder resist layer on the second side of the core layer and the second circuit layer, wherein a portion of a surface of the second circuit layer is exposed from the second solder resist layer; and removing the support member.

In some embodiments, the first solder resist layer is cured at a temperature of 130° C. so as to bake and cure the first solder resist layer and subsequently remove the carrier. Alternatively, the first solder resist layer is cured at a temperature of 160° C. so as to remove the carrier and subsequently bake and cure the first solder resist layer.

In some embodiments, the present disclosure further comprises: before removing the carrier, forming a surface treatment layer on the first circuit layer exposed from the first solder resist layer. Alternatively, the present disclosure further comprises: after removing the carrier, forming a protective layer on the second side of the core layer, forming a surface treatment layer on the first circuit layer exposed from the first solder resist layer, and removing the protective layer.

In some embodiments, a thickness of the metal layer is 2 microns to 3 microns.

In some embodiments, the steps of forming the through holes comprise: providing the substrate having a metal protective layer on each of the metal layers; bonding the substrate to each of opposite sides of a carrier board, and pressing the substrate to the carrier board by the metal protective layer on the first side of the core layer; removing the metal protective layer on the second side of the core layer; forming a plurality of first vias extending into the core layer on the metal layer on the second side of the core layer, wherein the first vias are correspondingly located at the second side and do not penetrate through the core layer; removing the carrier board; bonding the second side of the core layer to each of opposite sides of the carrier, wherein the carrier caps the first vias; and forming a plurality of second vias communicating with the first vias on the metal layer on the first side of the core layer.

As can be seen from the above, in the package substrate and manufacturing method thereof of the present disclosure, by combining two extremely thin substrates to be processed on opposite sides of the carrier (and/or the support member), the structural thickness required for the manufacturing process is increased such that the processability of the ultra-thin substrate is not limited by the performance of the equipment, thereby achieving the capability of the equipment with the minimum board thickness. Therefore, compared to the prior art, the manufacturing method of the present disclosure can process any substrate having ultra-thin thickness by using conventional processing equipment, thereby eliminating the need for specialized equipment and significantly reducing processing costs.

### BRIEF DESCRIPTION OF THE DRAWINGS

FIG. 1A to FIG. 1G are schematic cross-sectional views showing a manufacturing method of a package substrate according to a first embodiment of the present disclosure.

FIG. 2A to FIG. 2E are schematic cross-sectional views showing a manufacturing method of a package substrate according to a second embodiment of the present disclosure.

FIG. 3A to FIG. 3B are schematic cross-sectional views showing a manufacturing method of a package substrate according to a third embodiment of the present disclosure.

FIG. 4A to FIG. 4B are schematic cross-sectional views showing a manufacturing method of a package substrate according to a fourth embodiment of the present disclosure.

FIG. 5A to FIG. 5D are schematic cross-sectional views showing a manufacturing method of a package substrate according to a fifth embodiment of the present disclosure.

FIG. 6A to FIG. 6B are schematic cross-sectional views showing a manufacturing method of a package substrate according to a sixth embodiment of the present disclosure.

### DETAILED DESCRIPTION

The following describes the implementation of the present disclosure with examples. Those skilled in the art can easily understand other advantages and effects of the present disclosure from the content disclosed in this specification.

It should be understood that, the structures, ratios, sizes, and the like in the accompanying figures are used for illustrative purposes to facilitate the perusal and comprehension of the content disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical content disclosed in the present specification. Meanwhile, terms such as “on,” “in,” “inside,” “out,” “outside,” “a,” “one,” and the like are merely for clear explanation rather than limiting the practicable scope of the present disclosure, and thus, alterations or adjustments of the relative relationships thereof without essentially altering the technical content should still be considered in the practicable scope of the present disclosure.

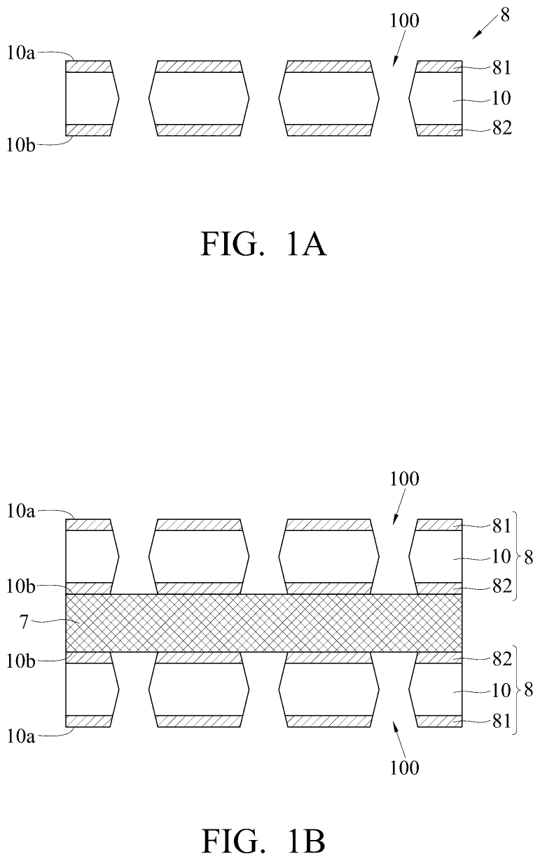

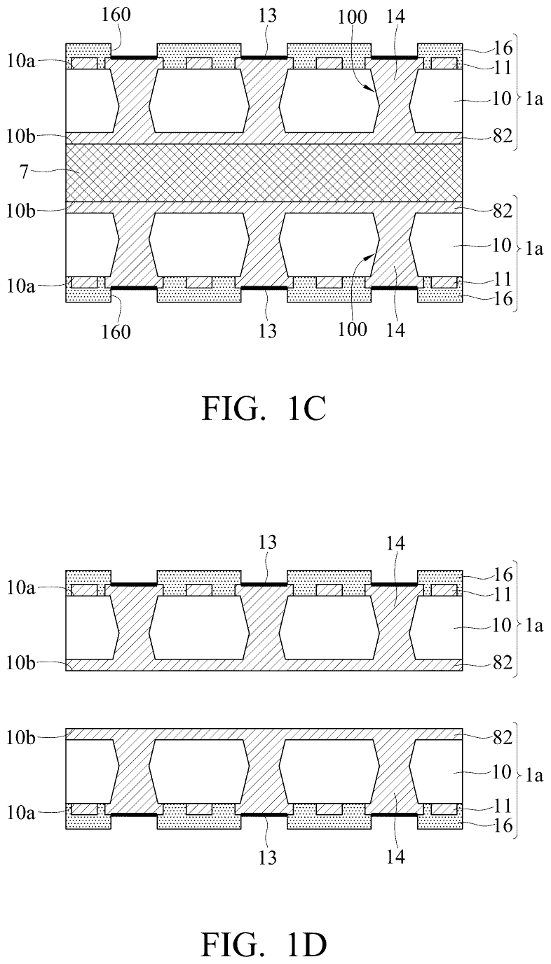

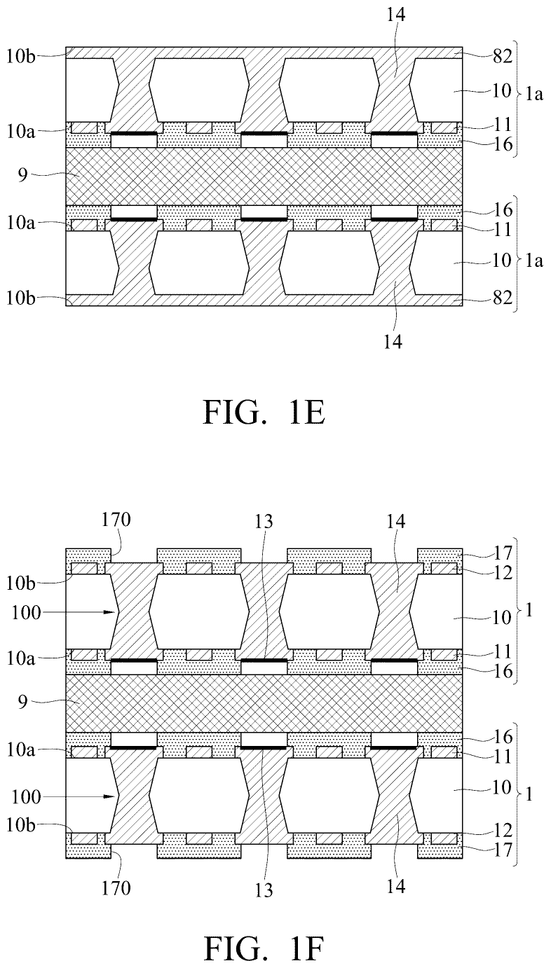

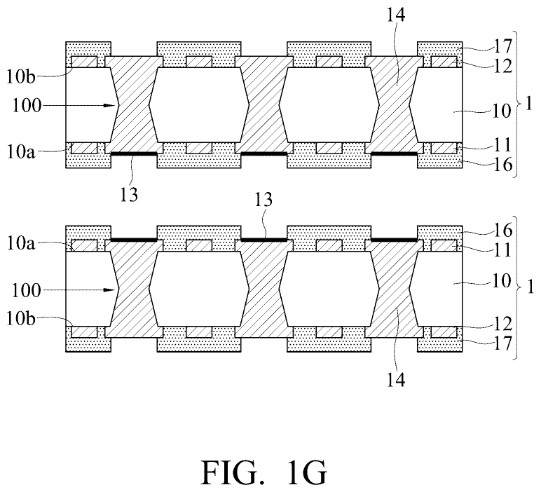

FIG. 1A to FIG. 1G are schematic cross-sectional views showing an exemplary manufacturing method of a package substrate 1 according to the present disclosure.

As shown in FIG. 1A, a substrate 8 is provided. The substrate 8 includes a core layer 10 having a plurality of through holes 100 and metal layers 81, 82 respectively formed on opposite surfaces of the core layer 10.

In an embodiment, the substrate 8 is a copper foil substrate, and the core layer 10 has a first side 10a and a second side 10b opposite to the first side 10a. For example, the core layer 10 is made of high-hardness dielectric material, such as glass, ceramic, SiC, AlO₂, or composite material, and the thickness thereof is 40 micrometers (μm). In addition, the metal layer 81, 82 is a copper foil, and the thickness thereof is 2 μm.

Moreover, the through holes 100 communicate the first side 10a with the second side 10b and are in the shape of a double tapered hole, such as an hourglass-shaped type or an X-shaped type. For example, a combination of laser and plasma is used to form the plurality of through holes 100.

As shown in FIG. 1B, the substrate 8 is bonded to each of opposite sides of a carrier 7. Each substrate 8 is bonded to the carrier 7 by the second side 10b of the core layer 10.

In an embodiment, the carrier 7 is a thermally dissociable adhesive tape or an adhesive temporary removable sheet. Portions of the surfaces of the carrier 7 are exposed through the through holes 100.

As shown in FIG. 1C, a patterned wiring process is carried out to form a first circuit layer 11 on the first side 10a of the core layer 10 by means of the metal layer 81, and a conductive pillar 14 electrically connected to the first circuit layer 11 is formed in each of the through holes 100. Subsequently, a first solder resist layer 16 is formed on the first side 10a of the core layer 10 and the first circuit layer 11 such that a portion of the surface of the first circuit layer 11 is exposed from the first solder resist layer 16 to form a circuit structure 1a.

In an embodiment, copper is first formed on the surface of the metal layer 81, the wall of each of the through holes 100 and the exposed surface of the carrier 7 by chemical plating, and then a photoresist (not shown) is subjected to the exposure and development process, so that the first circuit layer 11 is formed by electroplating in the patterned photoresist. Subsequently, the photoresist and the copper and the metal layer 81 underneath the photoresist are removed.

Moreover, the first solder resist layer 16 having a plurality of first openings 160 exposing the first circuit layer 11 may be formed by exposure and development, and then the first solder resist layer 16 may be baked at a temperature of 130° C./1 hour. Further, after baking and curing the first solder resist layer 16, a surface treatment process, such as electroplating with nickel/gold, may be performed for use as a surface treatment layer 13.

As shown in FIG. 1D, after forming the surface treatment layer 13, the carrier 7 is removed to obtain a plurality of the circuit structures 1a.

As shown in FIG. 1E, the circuit structure 1a is bonded to each opposite sides of a support member 9. The circuit structure 1a is bonded to the support member 9 by the first side 10a of the core layer 10 thereof.

In an exemplary embodiment, the support member 9 is a thermally dissociable adhesive tape or an adhesive temporary removable sheet, such as a thermally dissociable film in the form of a double-sided sticker, so that the circuit structure 1a is pressed on each side of the support member 9 such that the first solder resist layer 16 is bonded to the support member 9.

As shown in FIG. 1F, a second circuit layer 12 electrically connected to the conductive pillars 14 is formed on the second side 10b of the core layer 10 of each of the circuit structures 1a by means of the metal layer 82. Subsequently, a second solder resist layer 17 is formed on the second side 10b of the core layer 10 and the second circuit layer 12 such that a portion of the surface of the second circuit layer 12 is exposed from the second solder resist layer 17 so as to form the package substrate 1.

In an exemplary embodiment, an exposure and development process of a photoresist (not shown) is first performed on the surface of the metal layer 82, so that the second circuit layer 12 is formed by electroplating in the patterned photoresist. Subsequently, the photoresist and the metal layer 82 underneath the photoresist are removed.

Further, the second solder resist layer 17 having a plurality of second openings 170 exposing the second circuit layer 12 may be formed by exposure and development.

As shown in FIG. 1G, the support member 9 is removed to obtain a plurality of the package substrates 1.

In an exemplary embodiment, the second solder resist layer 17 may be baked and then subjected to plasma operations and related post-processing processes, such as an organic solderability preservative (OSP).

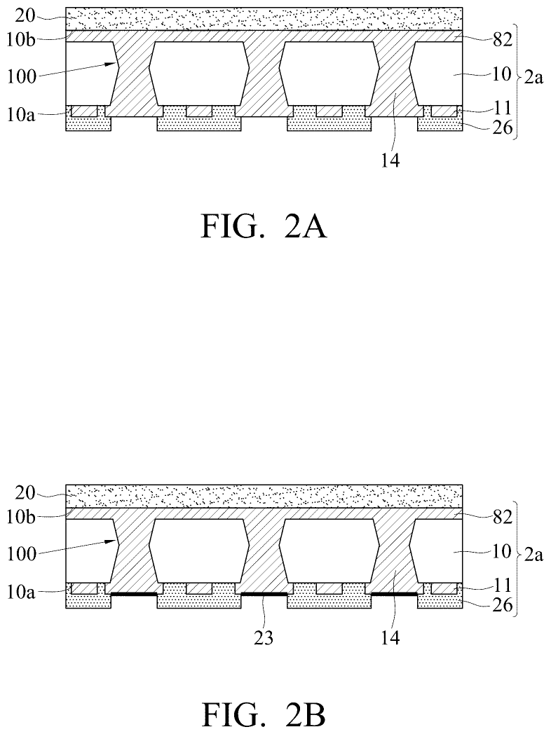

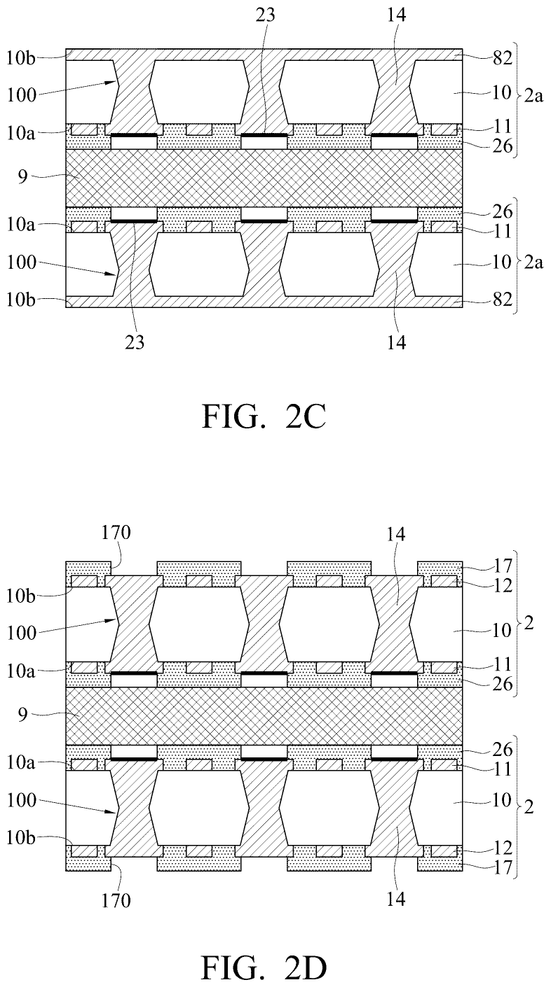

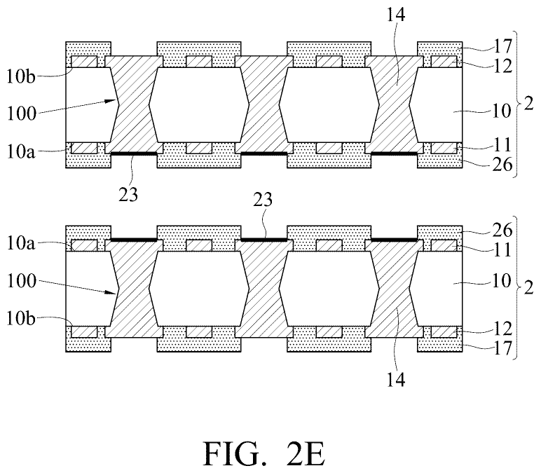

In another exemplary embodiment, the surface treatment layer 13 has not been formed before removing the carrier 7. Accordingly, after removing the carrier 7 (i.e., continuing the manufacturing process shown in FIG. 1D), a protective layer 20 such as an anti-plating film is formed on the second side 10b of the core layer 10 of a circuit structure 2a, as shown in FIG. 2A, and then a surface treatment layer 23 such as a nickel/gold layer is formed by electroplating the exposed surface of the first circuit layer 11, as shown in FIG. 2B. After that, the protective layer 20 is removed, and the circuit structure 2a is bonded to each of opposite sides of the support member 9, as shown in FIG. 2C, to manufacture the second circuit layer 12, as shown in FIG. 2D. Finally, a plurality of package substrates 2 are obtained, as shown in FIG. 2E.

It should be noted that in the manufacturing process of FIG. 2A to FIG. 2E, it is not necessary to bake the first solder resist layer 26 before removing the carrier 7. As such, after removing the carrier 7, it is necessary to bake the first solder resist layer 26 at a temperature of 160° C./1 hour before forming the protective layer 20.

Therefore, the decomposition temperature of the carrier 7 may be higher or lower than the curing temperature of the first solder resist layer 16, 26. For example, in the manufacturing process of FIG. 1C to FIG. 1D, the decomposition temperature of the carrier 7 is higher than the curing temperature (130° C.) of the first solder resist layer 16, and thus it is necessary to separate the carrier 7 only after surface treatment (i.e., after forming the surface treatment layer 13). On the other hand, in the manufacturing process of FIG. 1D and FIG. 2A to FIG. 2B, the decomposition temperature of the carrier 7 is lower than the curing temperature of the first solder resist layer 26 (160° C.), and therefore, it is necessary to separate the carrier 7 before curing the first solder resist layer 26 (i.e., before baking the first solder resist layer 26).

Moreover, the process is applicable to various surface treatments and is also applicable to substrate specifications with different surface treatments on both sides, so as to shorten the production process and increase the production efficiency. For example, in the manufacturing process of FIG. 1C to FIG. 1D, the carrier 7 is resistant to the various surface treatment layers 13 such as electroless gold plating, electroless nickel palladium gold plating and gold electroplating. On the other hand, if the carrier 7 is not able to resist the manufacturing method of the various surface treatment layers 23 such as electroless gold plating, electroless nickel palladium gold plating and gold electroplating, the surface treatment layer 23 is formed by the configuration of the protective layer 20 in the manufacturing process of FIG. 1D and FIG. 2A to FIG. 2B.

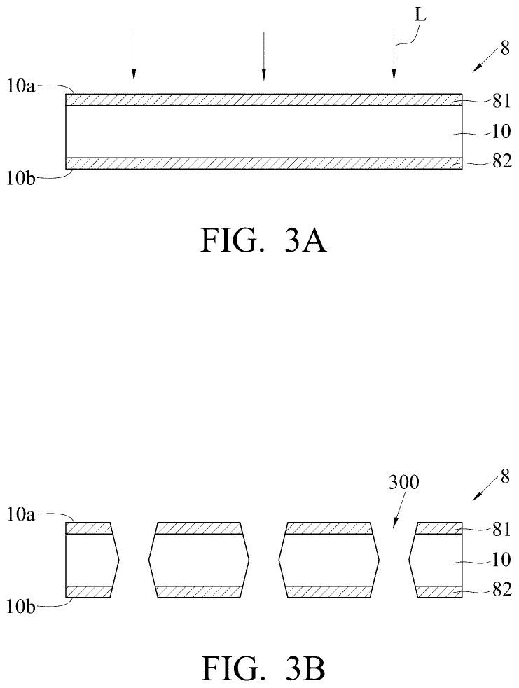

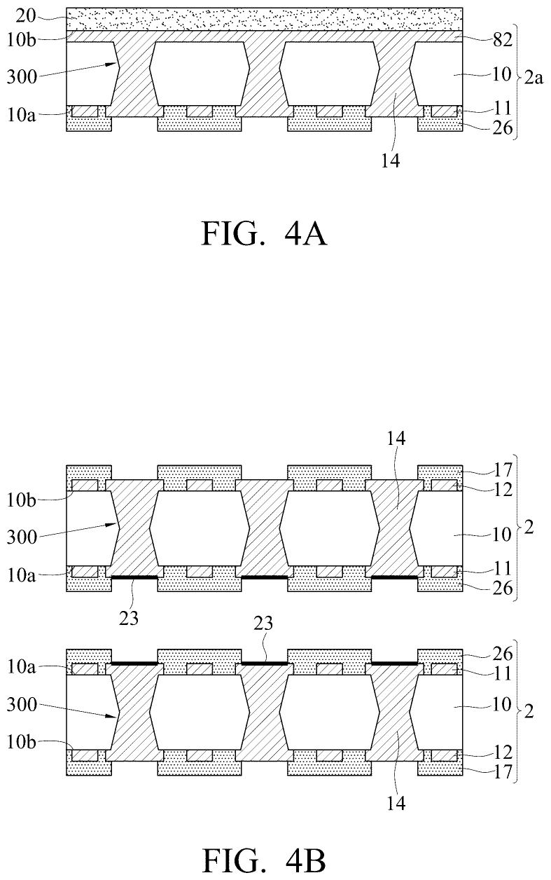

Further, as shown in FIG. 3A to FIG. 3B, a picosecond laser L may be used to form a plurality of through holes 300 to omit the use of a plasma method, and then the manufacturing process shown in FIG. 1B to FIG. 1G is carried out. Alternatively, after the picosecond laser L is used to form the plurality of through holes 300, steps such as manufacturing the first circuit layer 11 and the circuit structure 2a can be performed by the manufacturing process shown in FIG. 2A to FIG. 2E, as shown in FIG. 4A to FIG. 4B. It should be noted that the thickness of the metal layers 81, 82 is 3 μm when using a picosecond laser.

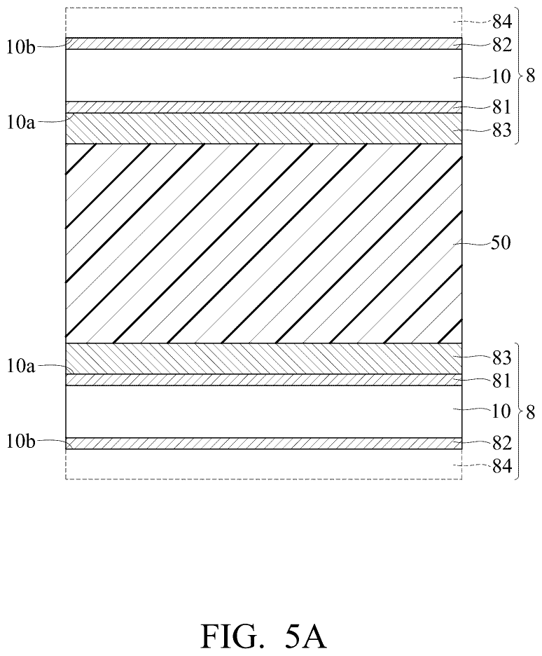

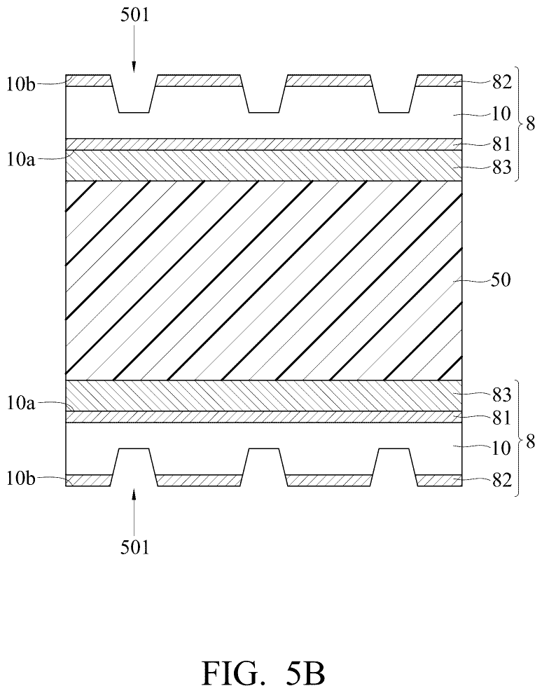

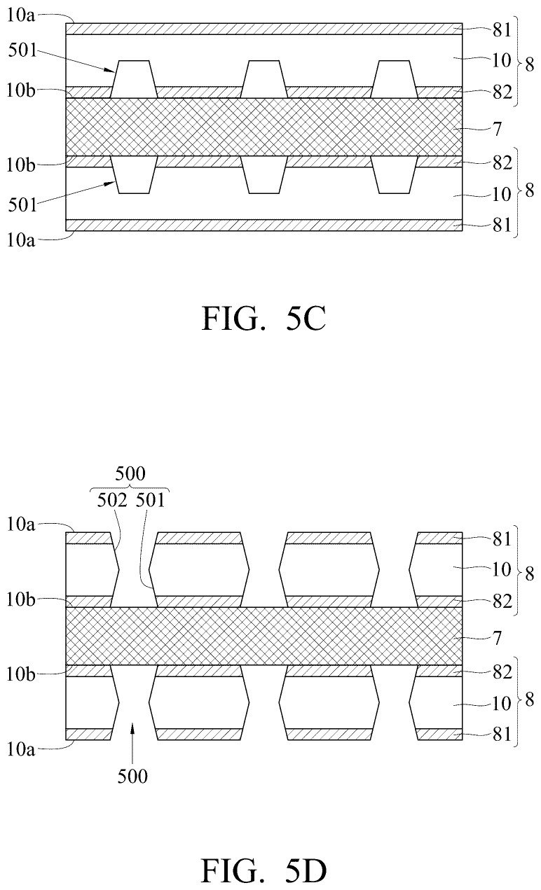

Alternatively, the manufacturing process of through holes 500 may be accomplished on the carrier 7. As shown in FIG. 5A, a metal protective layer 83, 84 is provided on the surfaces of the metal layers 81, 82 of the substrate 8 so as to bond the substrate 8 on each of opposite sides of a carrier board 50, the substrate 8 is pressed to the carrier board 50 by the metal protective layer 83 on the first side 10a of the core layer 10, and the metal protective layer 84 on the second side 10b of the core layer 10 is then removed. Subsequently, as shown in FIG. 5B, laser and plasma are used on the surface of the metal layer 82 on the second side 10b of the core layer 10 to form a plurality of first vias 501 extending into the core layer 10, which do not penetrate through the core layer 10. Subsequently, as shown in FIG. 5C, the carrier board 50 is removed, and the second side 10b of the core layer 10 is bonded to each of opposite surfaces of the carrier 7 to cap the first vias 501. Finally, as shown in FIG. 5D, black oxide treatment is performed on the copper surface of the substrate 8 (i.e., the metal layer 81), and then second vias 502 communicating with the first vias 501 are formed on the metal layer 81 on the first side 10a of the core layer 10 by using laser and plasma so as to form the plurality of through holes 500.

For example, the thickness of the carrier board 50 is 133 μm. In addition, the thickness of the metal protective layer 83, 84 is 18 μm, and the thickness of the metal layer 81, 82 is 3 μm. Further, the metal protective layer 83, 84 is a copper sheet to facilitate removal, and the carrier board 50 is made of prepreg (PP) or other dielectric materials.

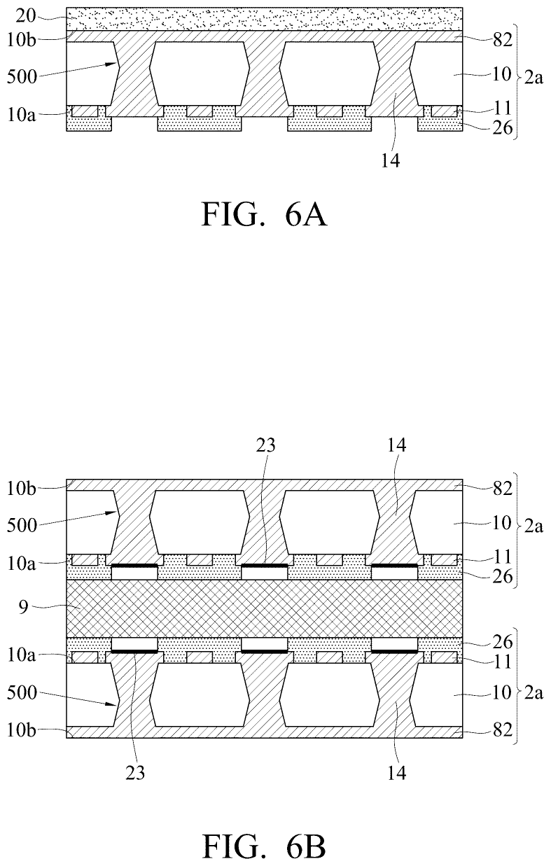

It should be appreciated that after manufacturing the through holes 500, the first circuit layer 11, the conductive pillars 14, the first solder resist layer 16, the second circuit layer 12 and the second solder resist layer 17 are manufactured successively, and the process may also be carried out in the manner shown in FIG. 2A to FIG. 2E, as shown in FIG. 6A to FIG. 6B.

Therefore, in the package substrate 1, 2 and manufacturing method thereof of the present disclosure, by combining two extremely thin substrates 8 to be processed on opposite sides of the carrier 7 and opposite sides of the support member 9, the structural thickness required for the process is increased such that the processability of the ultra-thin substrate 8 having double tapered through holes 100, 300, 500 is not limited by the performance of the equipment, thereby achieving the capability of the equipment with the minimum board thickness. Therefore, compared to the prior art, the manufacturing method of the present disclosure can process any substrate 8 having ultra-thin thickness (e.g., the thickness of the substrate 8 may be 0.01 mm, 0.015 mm, 0.02 mm, 0.03 mm, 0.04 mm, etc.) in the aforesaid manners by using conventional processing equipment, thereby eliminating the need for specialized equipment and significantly reducing processing costs.

Furthermore, the ultra-thin substrate 8 having double tapered through holes 100, 300, 500 can be formed in a variety of ways and is not limited by equipment and materials. For example, in the manufacturing process of FIG. 1A (or FIG. 2A), a bright copper layer having a thickness of 2 μm is used for processing, and thus black oxide treatment is not required; in the manufacturing process of FIG. 3A to FIG. 3B (or FIG. 4A), a bright copper layer having a thickness of 3 μm is used, and a picosecond laser L is used to process the bright copper layer, and thus black oxide treatment is not required; in the process of FIG. 5A to FIG. 5D (or FIG. 6A), it is necessary to first use the metal protective layer 83, 84 to cap the metal layer 81, 82, and then the metal protective layer 83 is pressed to the carrier board 50 made of prepreg or other dielectric materials to increase the thickness of the board to achieve the capability of the equipment, and subsequently the black oxide treatment operation is required.

Also, the first circuit layer 11 and the second circuit layer 12 are manufactured separately. As a result, the manufacturing method of the present disclosure is applicable to the wiring specifications of the substrate 8 where there is a large difference in copper thickness on both sides thereof, thereby shortening the production process and further improving the production efficiency.

The present disclosure also provides a package substrate 1, 2, which comprises: a core layer 10, a first circuit layer 11, a first solder resist layer 16, 26, a second circuit layer 12, a second solder resist layer 17, and a plurality of conductive pillars 14.

The core layer 10 has a first side 10a, a second side 10b opposite to the first side 10a, and a plurality of through holes 100, 300, 500 communicating the first side 10a with the second side 10b. The through holes 100, 300, 500 are double tapered holes.

The first circuit layer 11 is formed on the first side 10a of the core layer 10.

The first solder resist layer 16, 26 is formed on the first side 10a of the core layer 10 and the first circuit layer 11. A portion of the surface of the first circuit layer 11 is exposed from the first solder resist layer 16, 26.

The second circuit layer 12 is formed on the second side 10b of the core layer 10.

The second solder resist layer 17 is formed on the second side 10b of the core layer 10 and the second circuit layer 12. A portion of the surface of the second circuit layer 12 is exposed from the second solder resist layer 17.

The conductive pillar 14 is formed in each of the plurality of through holes 100, 300, 500 and electrically connects the first circuit layer 11 and the second circuit layer 12.

In an embodiment, the first solder resist layer 16, 26 is cured at a temperature of 130° C. or 160° C.

In an embodiment, the package substrate 1, 2 further comprises: a surface treatment layer 13, 23 formed on the first circuit layer 11 exposed from the first solder resist layer 16, 26.

In an embodiment, each of the through holes 500 comprises a first via 501 and a second via 502 communicating with the first via 501. The first via 501 is correspondingly located at the second side 10b, and the second via 502 is correspondingly located at the first side 10a.

In summary, in the package substrate and manufacturing method thereof of the present disclosure, by combining two extremely thin substrates to be processed on opposite sides of the carrier (and/or the support member), the structural thickness required for the process is increased such that the processability of the ultra-thin substrate having double tapered through holes is not limited by the performance of the equipment, thereby achieving the capability of the equipment with the minimum board thickness. Therefore, the manufacturing method of the present disclosure can process any substrate having ultra-thin thickness by using conventional processing equipment, thereby eliminating the need for specialized equipment and significantly reducing processing costs.

The above embodiments are provided for illustrating the principles of the present disclosure and its technical effect and should not be construed as to limit the present disclosure in any way. The above exemplary embodiments can be modified by one of ordinary skill in the art without departing from the spirit and scope of the present disclosure. Therefore, the scope claimed of the present disclosure should be defined by the following claims.

What is claimed is:

1. A package substrate, comprising:
a core layer having a first side, a second side opposite to the first side, and a plurality of through holes communicating the first side with the second side, wherein the through holes are double tapered holes;
a first circuit layer formed on the first side of the core layer;
a first solder resist layer formed on the first side of the core layer and the first circuit layer, wherein a portion of a surface of the first circuit layer is exposed from the first solder resist layer;
a second circuit layer formed on the second side of the core layer;
a second solder resist layer formed on the second side of the core layer and the second circuit layer; and
a conductive pillar formed in each of the plurality of through holes and electrically connecting the first circuit layer and the second circuit layer.

2. The package substrate of claim 1, wherein the first solder resist layer is cured at a temperature of 130° C. or 160° C.

3. The package substrate of claim 1, further comprising: a surface treatment layer formed on the first circuit layer exposed from the first solder resist layer.

4. The package substrate of claim 1, wherein each of the through holes includes a first via and a second via communicating with the first via, the first via is correspondingly located at the second side, and the second via is correspondingly located at the first side.

5. A method of manufacturing a package substrate, comprising:
providing a substrate including a core layer and a metal layer formed on each of opposite surfaces of the core layer, wherein the core layer has a first side, a second side opposite to the first side, and a plurality of through holes communicating the first side with the second side, wherein the through holes are double tapered holes;
bonding the substrate to each of opposite sides of a carrier, wherein each of the substrates is bonded to the carrier by the second side of the core layer;
forming a first circuit layer on the first side of the core layer by means of the metal layer and forming a conductive pillar electrically connected to the first circuit layer in each of the plurality of through holes;
forming a first solder resist layer on the first side of the core layer and the first circuit layer, wherein a portion of a surface of the first circuit layer is exposed from the first solder resist layer;
removing the carrier;
bonding the substrate to each of opposite sides of a support member, wherein each of the substrates is bonded to the support member by the first solder resist layer on the first side thereof;
forming a second circuit layer electrically connected to the conductive pillar by means of the metal layer on the second side of the core layer;
forming a second solder resist layer on the second side of the core layer and the second circuit layer, wherein a portion of a surface of the second circuit layer is exposed from the second solder resist layer; and
removing the support member.

6. The method of claim 5, wherein the first solder resist layer is cured at a temperature of 130° C. so as to bake and cure the first solder resist layer and subsequently remove the carrier.

7. The method of claim 5, wherein the first solder resist layer is cured at a temperature of 160° C. so as to remove the carrier and subsequently bake and cure the first solder resist layer.

8. The method of claim 5, further comprising: before removing the carrier, forming a surface treatment layer on the first circuit layer exposed from the first solder resist layer.

9. The method of claim 5, further comprising: after removing the carrier, forming a protective layer on the second side of the core layer, forming a surface treatment layer on the first circuit layer exposed from the first solder resist layer, and removing the protective layer.

10. The method of claim 5, wherein steps of forming the through holes comprise:
providing the substrate having a metal protective layer on each of the metal layers;
bonding the substrate to each of opposite sides of a carrier board, and pressing the substrate to the carrier board by the metal protective layer on the first side of the core layer;
removing the metal protective layer on the second side of the core layer;
forming a plurality of first vias extending into the core layer on the metal layer on the second side of the core layer, wherein the first vias are correspondingly located at the second side and do not penetrate through the core layer;
removing the carrier board;
bonding the second side of the core layer to each of opposite sides of the carrier, wherein the carrier caps the first vias; and
forming a plurality of second vias communicating with the first vias on the metal layer on the first side of the core layer.
